(19) United States
(12) Patent Application Publication
(10) Pub. No.: US 2024/0332535 A1
(43) Pub. Date: Oct. 3, 2024

(54) PASSIVATION LAYER, PREPARATION METHOD THEREFOR AND APPLICATION THEREOF

(71) Applicant: SHENZHEN YUANSU OPTOELECTRONICS TECHNOLOGY CO., LTD., SHENZHEN, Guangdong (CN)

(72) Inventors: Weizhen WANG, SHENZHEN, Guangdong (CN); Yanlong BAI, SHENZHEN, Guangdong (CN); Zhefeng LI, SHENZHEN, Guangdong (CN); Ann Lincu XIN, SHENZHEN, Guangdong (CN); Lu SHEN, SHENZHEN, Guangdong (CN); Luoyuan XIE, SHENZHEN, Guangdong (CN)

(21) Appl. No.: 18/580,131

(22) PCT Filed: Aug. 19, 2022
(86) PCT No.: PCT/CN2022/113713

§ 371 Date: Jan. 17, 2024

(30) Foreign Application Priority Data
Aug. 27, 2021 (CN) 202110994215X

(51) Int. Cl. H01M 4/62; C01B 25/45; C01B 33/20; C01G 49/00; C01G 51/00; C01G 53/00; C23C 14/08; C23C 14/35; C23C 16/40; C23C 16/44; C23C 16/455; C23C 16/458; H01M 4/02; H01M 4/04; H01M 4/133; H01M 4/1393; H01M 4/587; H01M 10/0525

(52) U.S. Cl. CPC H01M 4/628; C01B 25/45; C01B 33/20; C01G 49/0045; C01G 51/006; C01G 51/40; C01G 53/40; C23C 14/081; C23C 14/35; C23C 16/402; C23C 16/403; C23C 16/405; C23C 16/406; C23C 16/408; C23C 16/4408; C23C 16/45527; C23C 16/45555; C23C 16/4583; H01M 4/0426; H01M 4/0428; H01M 4/133; H01M 4/1393; H01M 4/587; H01M 10/0525; C01P 2006/40; H01M 2004/027

(57) ABSTRACT

Disclosed are a passivation layer (200), a preparation method therefor and an application thereof. The passivation layer (200) comprises a first passivation layer (210), the first passivation layer (210) being disposed adjacent to a secondary battery negative electrode plate (100) and having ionic conductivity and a thickness of 0.1-10 nm. The passivation layer (200) also comprises a second passivation layer (220), the second passivation layer (210) being disposed at a side surface of the first passivation layer (210) distant from the negative electrode plate (100) of the secondary battery, comprising a corrosion-resistant material and having a thickness of 0.1-5 nm. The passivation layer (200) has the effect of increasing safety performance and cycle performance of a secondary battery. The preparation method is simple and has high applicability. Furthermore, the obtained passivation layer (200) can be applied in multiple types of batteries and multiple fields.

### TECHNICAL FIELD

The present disclosure belongs to the technical field of secondary batteries, and specifically relates to a passivation layer, and preparation method and use thereof.

### BACKGROUND

During the first charge and discharge process of conventional liquid secondary battery (including lithium-ion battery), the electrode material reacts with the electrolyte on the solid-liquid interface, forming an electrode protective layer covering the surface of negative electrode. Such electrode protective layers have the characteristics of solid electrolyte, which can block the electrolyte molecules passing through and allow the active metal ions (lithium ions in lithium-ion batteries) to shuttle in it, thus protecting the negative electrode active material to a certain extent, and it is called solid electrolyte interface film (SEI film).

However, the naturally generated SEI film is unstable during charge and discharge cycles of the secondary battery. Particularly under high temperature conditions, the SEI film is prone to rupture or delamination, leading to the erosion of the active material in negative electrode by the electrolyte. It not only weakens the capacity of the secondary battery but also easily poses safety hazards.

In order to solve the related technical problems, researchers propose to prepare a passivation protective layer on the surface of the negative plate so as to protect active materials in negative electrode. For example, using atomic layer deposition (ALD) to from a passivation protective film.

Such protective film has a compact structure, and can cover the negative surface with complex surface structure without gaps. At the same time, it maintains stable chemical properties during the charge and discharge processes of secondary battery, which is beneficial to prolonging the cycle life of the secondary battery such as lithium-ion secondary battery greatly.

The ALD passivation film materials used by related technology are mostly conventional aluminum oxide and hafnium oxide (Al₂O₃ and HfO₂) etc, and the ALD preparation process for such material is mature and has quite excellent chemical stability.

However, the protective layer provided by the conventional technology can not provide a good protective effect if the thickness is too thin, or will affect the working performance of the secondary battery if the thickness is too thick.

### SUMMARY

The present disclosure aims to solve at least one of the technical problems in prior art.

Therefore, the first aspect of the present disclosure provides a passivation layer. Due to the limitations of the material properties and the thickness of the first passivation layer and the second passivation layer in the passivation layer, it has a protection performance on negative electrode plate without affecting working performance.

The second aspect of the present disclosure provides a preparation method for the passivation layer.

The third aspect of the present disclosure further provides a negative electrode with the aforementioned passivation layer.

The fourth aspect of the present disclosure further provides a secondary battery with the aforementioned negative electrode.

The fifth aspect of the present disclosure further provides use of the secondary battery in the fields of 3C, energy storage and power batteries.

According to the first aspect of the present disclosure, provides a passivation layer, the passivation layer comprises:
a first passivation layer, wherein the first passivation layer is set on the surface of the negative electrode plate of the secondary battery, having ionic conductivity and a thickness of 0.1-10 nm;
a second passivation layer, wherein the second passivation layer is set on the surface of the first passivation layer on one side away from the negative electrode plate of the secondary battery, wherein comprising a corrosion-resistant material, with a thickness of 0.1-5 nm.

The passivation layer according to the embodiment of the present disclosure at least has the following beneficial effects.

(1) The passivation layer according to the present disclosure is attached to the surface of negative electrode plate and has physical protection effect on the negative electrode plate. That is, physically isolating the direct contact between the negative electrode plate and the electrolyte, so that the corrosion of the negative electrode active substance by the electrolyte can be avoided. If the secondary battery comprises the electrode protective layer provided by the present disclosure, the safety performance and the cycle stability of the secondary battery can be effectively improved.

(2) In the passivation layer of present disclosure, the first passivation layer has ionic conductivity, and can ensure that active ions (including lithium ions, sodium ions, potassium ions, aluminum ions and the like) of the secondary battery enter and desorb from the first passivation layer through mechanisms such as lattice intercalation-deintercalation, oxidation-reduction reaction or alloying reaction. That is to say, the aforementioned first passivation layer not only has the physical protection effect, but also has the characteristics of negative electrode active material, so that coating the first passivation layer on the surface of the negative electrode plate of the secondary battery does not affect the ion transmission performance of the battery, and also greatly improves the battery performance, such as the cycle performance of the lithium-ion battery. And its requirement for thickness precision is low, which can form a thicker coating and provide reliable passivation protection effect for the negative electrode.

(3) In the passivation layer of present disclosure, the second passivation layer directly contacts with the electrolyte, the material comprises corrosion-resistant material. The corrosion-resistant material has extremely strong chemical and electrochemical stability, so that it can resist the corrosion of the electrolyte. It further has excellent physical protection performance on the first passivation layer and the negative electrode plate of the secondary battery. Meanwhile, it can weaken volume change caused by the intercalation and desorption of the active ions (including lithium ions), thereby more stably improving the cycle performance of the lithium-ion battery. In addition, since the thickness of the second passivation layer is thin, the passage of ions is not blocked. That is, the performance of the secondary battery comprises the passivation layer does not be inhibited.

(4) In the passivation layer provided by the present disclosure, a synergistic effect occurs between the first passivation layer and the second passivation layer. Specifically, the first passivation layer serves as the first physical protection layer, while also has the function of improving the electrochemical performance. However, the simple first passivation layer may still be corroded due to insufficient inertia to the electrolyte. The second passivation layer resists the corrosion of electrolyte and protects the first passivation layer and the negative electrode plate of the secondary battery. However, the simple second passivation layer will affect the deintercalation of ions. Therefore, by optimizing the thickness of the first passivation layer and the second passivation layer, they both protect and support each other, thereby obtaining a passivation layer that can improve the safety and cycling performance of the negative electrode.

According to some embodiments of the present disclosure, in the first passivation layer, the ionic conductivity is at least one of lithium ion conductivity, sodium ion conductivity, aluminum ion conductivity and potassium ion conductivity.

According to some embodiments of the present disclosure, the first passivation layer comprises at least one of binary oxide and ternary oxide.

According to some embodiments of the present disclosure, the binary oxide has a general formula of AOₘ.

In the AOₘ, A is selected from at least one of the group consisting of V, Mo, Nb, Sb, Ge, Sn, Cd, In, Co, Ti, Fe, Mn, Ni, W, Cu, Mg, Si and Cr, and 1≤m≤3.

According to some preferred embodiments of the present disclosure, the AOₘ is selected from at least one of the group consisting of vanadium oxide, molybdenum oxide (MoO₃), niobium oxide (Nb₂O₅), antimony oxide (Sb₂O₃), germanium oxide (GeO₂), tin oxide (SnO₂), cadmium oxide (CdO), indium oxide (In₂O₃), cobalt oxide, titanium oxide (TiO₂), iron oxide, manganese oxide, nickel oxide (NiO), tungsten oxide (WO₃), copper oxide (CuO), magnesium oxide (MgO), silicon oxide (SiO₂) and chromium oxide (Cr₂O₃).

When the first passivation layer contains the silicon oxide, Li⁺ can be intercalated into the silicon oxide, so that Li—Si alloying is formed, and excellent lithium ion deintercalation performance and passivation protection performance are achieved.

According to some preferred embodiments of the present disclosure, the vanadium oxide is selected from at least one of the group consisting of VO, V₂O₃, VO₂ and VₖO₂ₖ₋₁, and k is natural number greater than or equal to 1.

According to some preferred embodiments of the present disclosure, the cobalt oxide comprises at least one of CoO, CO₃O₄ and a non-stoichiometric oxide of cobalt.

According to some preferred embodiments of the present disclosure, the iron oxide comprises at least one of FeO, Fe₂O₃, Fe₃O₄ and a non-stoichiometric oxide of iron.

According to some preferred embodiments of the present disclosure, the manganese oxide comprises at least one of MnO, Mn₂O₃, Mn₃O₄ and a non-stoichiometric oxide of manganese.

According to some preferred embodiments of the present disclosure, the AOₘ is at least one of CoO, NiO and CuO.

According to some preferred embodiments of the present disclosure, the AOₘ is at least one of CoO.

According to some embodiments of the present disclosure, the ternary oxide satisfies at least one of the general formulas shown as B₂SnO₄, CₙSnO₃, DSb₂O₆, XY₂O₄, Li₄Ti₅O₁₂, MgTi₂O₅ and TiNb₂O₇.

Further, in the B₂SnO₄, B is selected from at least one of the group consisting of Mg, Mn, Co and Zn;

Further, in the CₙSnO₃, C is selected from at least one of the group consisting of Ca, Sr, Li, Mg and Co, and 1≤n≤2;

Further, in the DSb₂O₆, D is selected from at least one of the group consisting of Co, Ni and Cu;

Further, in the XY₂O₄, X is selected from at least one of the group consisting of Mn, Fe, Co, Ni and Cu, Y is selected from at least one of the group consisting of Mn, Fe, Co, Ni and Cu, and the condition is that the X and the Y are different.

According to some embodiments of the present disclosure, the ternary oxide is CₙSnO₃, and the CₙSnO₃ comprises at least one of CaSnO₃, SrSnO₃, Li₂SnO₃, MgSnO₃ and CoSnO₃.

According to some embodiments of the present disclosure, the corrosion-resistant material is selected from at least one of the group consisting of Al₂O₃, HfO₂, SiO₂, ZrO₂, MgO, Si₃N₄, AlN, CaF₂, LiF, MgF₂, LiCO₃, Li₃PO₃ and LiPON.

According to some preferred embodiments of the present disclosure, the corrosion-resistant material comprises at least one of Al₂O₃ and HfO₂.

According to some embodiments of the present disclosure, the first passivation layer is a single-layer structure or a laminated-layer structure.

According to some embodiments of the present disclosure, the laminated structure refers to a structure formed by sequentially overlapping two or more substances having ionic conductivity, for example, it can be sequentially overlapping of 1 nm cobalt oxide layers and 1 nm NiO layers.

According to some preferred embodiments of the present disclosure, the first passivation layer has a thickness of 0.5-10 nm, such as can be 1 nm, 3 nm or 5 nm.

According to some preferred embodiments of the present disclosure, the second passivation layer has a thickness of 1-3 nm, such as can be 2 nm.

According to the second aspect of the present disclosure, provides a preparation method for the passivation layer, the preparation method is atomic layer deposition (ALD) method, chemical vapor deposition method, physical vapor deposition method or a combination thereof.

The preparation method for the passivation layer according to the embodiment of the present disclosure at least has the following beneficial effects:

The atomic layer deposition method, the chemical vapor deposition method and the physical vapor deposition method can achieve uniform deposition of films made of specific materials, and can accurately control the thickness. Meanwhile, it can prepare multi-component, double-layer, multi-layer or other nano-laminated structures by replacing the raw materials for preparation.

According to some embodiments of the present disclosure, the atomic layer deposition method (ALD method) comprises at least one of static atomic layer deposition method and dynamic atomic layer deposition method.

Since ALD method is generally performed at a lower temperature, and limited by the thermal activation energy, only a small number of atoms in the passivation layer can diffuse to the ideal lattice sites, resulting in the passivation layer obtained by ALD method generally having an amorphous structure. The amorphous structure generally has superior corrosion resistance compared to crystalline material of the same composition, and the mechanism is that the amorphous material does not have crystal defects such as grain boundaries or dislocations, which are easily eroded by external liquid or gas. Therefore, the electrode protective layer prepared by the present disclosure has good passivation protection effect due to the formation of compact amorphous structure.

The principle of atomic layer deposition is as follows: the single atomic layers are alternately chemically adsorbed on the surface of the sample through saturation, the adjacent adsorbed atomic layers react. When the adjacent adsorbed layers contain metal atoms and oxygen atoms, a dense metal oxide film is formed, so that the atomic layer deposition film has a compact structure, and there are almost no micropores and microcracks in the film layer. That is, the electrode protective layer has a compact structure, so that the double electrode protective layer prepared by atomic layer deposition has a good passivation protection effect.

According to some embodiments of the present disclosure, the static atomic layer deposition comprises the following steps:
A1. placing the negative electrode plate of the secondary battery in a chamber of an atomic layer deposition instrument, and first sequentially depositing an adsorption layer of a first precursor and an adsorption layer of a reactant on the surface of the negative electrode plate of the secondary battery, performing cyclic deposition based on the sequence to obtain a first passivation layer; the first precursor contains non-oxygen atoms in the first passivation layer;
A2. sequentially depositing an adsorption layer of a second precursor and an adsorption layer of a reactant on the surface of the first passivation layer of the component obtained in step A1 on one side away from the negative electrode plate of the secondary battery, performing cyclic deposition based on the sequence to obtain a second passivation layer; the second precursor contains non-oxygen atoms in the corrosion-resistant material.

According to some embodiments of the present disclosure, in step A1, the number of cyclic deposition is 1-50 times.

According to some embodiments of the present disclosure, in step A1, the deposition temperature of cyclic deposition is 50-350° C.

According to some preferred embodiments of the present disclosure, in step A1, the deposition temperature of the first passivation layer is 100-200° C.

For the material of the adsorption layer of the first precursor, examples are as follows:

For example, if the material of the first passivation layer is CoO, the first precursor contains Co.

According to some embodiments of the present disclosure, in step A1, the first precursor has a general formula of M-Rₙ, wherein M is the same as the non-oxygen atom in the first passivation layer, R is an organic group, and n is a coordination number.

According to some embodiments of the present disclosure, the R is ethoxy.

According to some preferred embodiments of the present disclosure, the preparation method of adsorption layer of the first precursor is: pulsing the first precursor into the reaction chamber of the ALD, wherein one pulse time (time to complete one valve opening-closing cycle) is between 0.1-5 s; after one pulse is completed, the pressure maintaining time is between 1-10 s; the adsorption layer of the first precursor requires a pulse count of 1-5 times; and the ALD chamber is purged with N₂ before and after the preparation of the adsorption layer of the first precursor, time is 1-90 s.

According to some preferred embodiments of the present disclosure, the raw material for preparation of adsorption layer of the reactant is at least one of ozone, oxygen plasma, ammonia plasma and nitrogen plasma.

According to some preferred embodiments of the present disclosure, the raw material for preparation of adsorption layer of the reactant is at least one of water, hydrogen peroxide, hexafluoroacetylacetone, carbon dioxide and trimethyl phosphate.

The reactant acts to react with the first precursor to form the first passivation layer.

According to some preferred embodiments of the present disclosure, the adsorption layer of the reactant can chemically react with the adsorption layer of the first precursor to form a chemical bond, and thus form the binary oxide or the ternary oxide.

According to some embodiments of the present disclosure, the preparation method of adsorption layer of the reactant is: pulsing the reactant into the chamber of the ALD, wherein one pulse time (time to complete one valve opening-closing cycle) is between 0.1-50 s; after one pulse is completed, the pressure maintaining time is between 1-10 s; the adsorption layer of the reactant requires a pulse count of 1-5 times; and the ALD chamber is purged with N₂ before and after the preparation of the adsorption layer of the reactant, time is 1-180 s.

According to some embodiments of the present disclosure, in the adsorption layer of the reactant, if the reactant is at least one of water, hydrogen peroxide, hexafluoroacetylacetone, carbon dioxide and trimethyl phosphate, the time for one pulse is between 0.1-5 s.

According to some embodiments of the present disclosure, in the adsorption layer of reactant, if the reactant is at least one of ozone, oxygen plasma, ammonia plasma and nitrogen plasma, the time for one pulse is between 1-50 s.

The adsorption layer of the first precursor and the adsorption layer of the reactant have a high activity, so that chemical reaction can occur between layers to generate chemical bonds and generate at least one of the binary oxides and the ternary oxides in the material of the first passivation layer.

The thickness of the first passivation layer can be adjusted by adjusting the number of cyclic depositions in step A1, the greater the number of cycles, the thicker the first passivation layer.

The structure of the first passivation layer can also be adjusted by adjusting the types of the first precursor, for example, for obtaining the multi-layer laminated structure, organic cobalt can be used as the first precursor in the 1^{st}-10^{th} cyclic depositions, and organic nickel is used as the first precursor in the 11^{th}-20^{th} cyclic deposition.

According to some embodiments of the present disclosure, in step A2, the deposition temperature of the second passivation layer is 50-350° C.

According to some preferred embodiments of the present disclosure, in step A2, the deposition temperature of cyclic deposition is 100-200° C.

According to some embodiments of the present disclosure, in step A2, the number of cyclic deposition is 1-5 times.

For the material of the adsorption layer of the second precursor, examples are as follows:

For example, if the material of the second passivation layer is Al₂O₃, the second precursor contains Al atoms.

According to some embodiments of the present disclosure, in step A2, the second precursor is M-Rn, wherein M is the non-oxygen atom forming the second passivation layer, R is an organic group, and n is a coordination number.

According to some embodiments of the present disclosure, the R is ethoxy.

According to some embodiments of the present disclosure, the first precursor and the second precursor may be the same or different according to the materials of the first passivation layer and the second passivation layer, for example, if the materials of the first passivation layer and the second passivation layer are both silicon oxide, the first precursor and the second precursor can be the same type of organosilicon.

According to some embodiments of the present disclosure, in step A2, the preparation method of the adsorption layer of the second precursor is the same as the preparation method of the adsorption layer of the first precursor in step A1, and the parameters can be the same or different.

According to some embodiments of the present disclosure, in step A2, the reactants and raw materials have the same selection range as the reactants described in step A1, and the specific selections can be the same or different.

According to some embodiments of the present disclosure, in step A2, the preparation method of the adsorption layer of the reactant is the same as the preparation method of the adsorption layer of a second reactant in step A1, and the parameters can be the same or different.

Same as step A2, the proportion of elements in the second passivation layer, the thickness of the second passivation layer, and the structure of the second passivation layer can also be adjusted by adjusting corresponding parameters in step A1.

According to some embodiments of the present disclosure, the dynamic atomic layer deposition comprises the following steps:
B1. placing the negative electrode plate of the secondary battery into the chamber of atomic layer deposition instrument under the protection of isolation gas, and then purging the chamber with flushing gas;
B2. introducing the first precursor and the reactant into the deposition area of the chamber in step B1, starting the mechanical moving mechanism at the same time, enabling the negative electrode plate of the secondary battery to move through the deposition area, and depositing the first passivation layer on the surface of the negative electrode plate of the secondary battery;
B3. in the operating state of the mechanical moving mechanism, introducing the second precursor and the reactant into the deposition region in step B2, and depositing the second passivation layer on the surface of the first passivation layer on one side away from the negative electrode plate of the secondary battery.

According to some embodiments of the present disclosure, in step B1, the negative electrode plate of the secondary battery is a coil stock or a sheet stock with a length of ≥500 mm.

According to some embodiments of the present disclosure, in step B1, the isolation gas has a flow rate of 10000-50000 sccm.

According to some embodiments of the present disclosure, in step B1, the flushing gas has a flow rate of 10000-50000 sccm.

According to some embodiments of the present disclosure, in step B2, the mechanical moving mechanism is roll-to-roll system.

According to some embodiments of the present disclosure, in step B2, the first precursor is introduced as the mixture of carrier gas and the first precursor.

According to some embodiments of the present disclosure, the mixture of the carrier gas and the first precursor has a flow rate of 1000-10000 sccm.

According to some embodiments of the present disclosure, in step B2, the reactant is introduced as the mixture of carrier gas and the reactant.

According to some embodiments of the present disclosure, the mixture of the carrier gas and the reactant has a flow rate of 1000-10000 sccm.

According to some embodiments of the present disclosure, in step B2, the motion is started after the first precursor and the reactant are stably introduced.

According to some embodiments of the present disclosure, in step B2, the motion is at the speed of 0.1-20 m/min.

According to some embodiments of the present disclosure, in step B2, the motion is at least one of unidirectional cyclic motion and bidirectional cyclic motion.

According to some embodiments of the present disclosure, in step B2, the first precursor and the reactant can be introduced simultaneously or may be introduced sequentially and cyclically.

According to some embodiments of the present disclosure, in step B3, the selection range of each parameter is the same as that in step B2, and the specific selection value can be the same or different.

According to some embodiments of the present disclosure, in step B3, the second precursor and the reactant can be introduced simultaneously or can be introduced sequentially and cyclically.

According to some embodiments of the present disclosure, the physical vapor deposition method is one of evaporation method, magnetron sputtering method and pulse laser deposition method.

According to some embodiments of the present disclosure, the magnetron sputtering method comprises the following steps:
C1. placing the negative electrode plate of the secondary battery into a high vacuum magnetron sputtering system;
C2. sputtering an intermediate layer target material by using a direct-current power supply, depositing on the surface of the negative electrode plate of the secondary battery to obtain an intermediate layer;
C3. sputtering an intermediate layer target material by using a direct-current power supply, depositing on the surface of the negative electrode plate of the secondary battery to obtain an intermediate layer;
C4. sputtering target material of the second passivation layer by using the radio frequency power supply, depositing the second passivation layer on the surface of the first passivation layer on one side away from the negative electrode plate of the secondary battery.

According to some embodiments of the present disclosure, in steps C1-C4, the deposition temperature of the first passivation layer and the second passivation layer is 10-100° C.

According to some embodiments of the present disclosure, the chemical vapor deposition method is one of atmospheric pressure chemical vapor deposition, low pressure chemical vapor deposition and plasma enhanced chemical vapor deposition.

According to some embodiments of the present disclosure, the low pressure chemical vapor deposition method comprises the following steps:
D1. placing the negative electrode plate of the secondary battery in the chamber of low pressure chemical vapor deposition system cleaned by flushing gas;
D2. simultaneously introducing the first precursor and the reactant into the chamber in step D1 to deposit the first passivation layer on the surface of the negative electrode plate of the secondary battery;
D3. simultaneously introducing the second precursor and the reactant into the chamber of step D2 to deposit the second passivation layer on the surface of the first passivation layer on one side away from the negative electrode plate of the secondary battery.

According to some embodiments of the present disclosure, in steps D1-D3, the deposition temperature of the first passivation layer and the second passivation layer is 100-900° C.

According to some preferred embodiments of the present disclosure, in steps D1-D3, the deposition temperature of the first passivation layer and the second passivation layer is 100-500° C.

According to some further preferred embodiments of the present disclosure, in steps D1-D3, the deposition temperature of the first passivation layer and the second passivation layers is 150-250° C.

Unless otherwise specified, the flushing gas, carrier gas, protective gas, isolation gas and the like are independently selected from at least one of the group consisting of nitrogen and inert gas.

According to the third aspect of the present disclosure, provides a negative electrode comprising a passivation layer, an active material, a binder, a conductive agent, and a current collector.

According to some embodiments of the present disclosure, the active material comprises at least one of graphite, graphene, carbon nanotubes, vapor grown carbon fibers, silicon carbon, silicon, lithium metal, sodium metal and transition metal oxides.

According to the type of active substance, it can be seen that the negative electrode can be used negative electrode can be used for various secondary batteries; for example, when the active material is one of graphite, graphene, carbon nanotubes, vapor grown carbon fibers, silicon carbon, silicon and transition metal oxides, the negative electrode can be used for at least one of lithium-ion battery, sodium ion battery, aluminum ion battery and potassium ion battery; when the active material is lithium metal, the negative electrode can be used for lithium metal battery; and when the active material is sodium metal, the negative electrode can be used for sodium metal battery.

Therefore, the negative electrode comprising the passivation layer provided by the present disclosure has a wide application range.

According to the negative electrode provided by the embodiment of the present disclosure, the negative electrode can have a better effect in maintaining the specific capacity of the lithium battery due to the use of the passivation layer mentioned above.

According to some embodiments of the present disclosure, the binder comprises, but is not limited to, polyvinylidene fluoride, polystyrene butadiene copolymer and the like.

According to a fourth aspect of the present disclosure, provides a secondary battery comprising the negative electrode.

According to some embodiments of the present disclosure, the secondary battery further comprises a positive electrode corresponding to the negative electrode, and an electrolyte.

According to some embodiments of the present disclosure, the secondary battery is at least one of a liquid battery and a solid battery.

When the secondary battery is a liquid battery, the secondary battery further comprises a separator.

According to some embodiments of the present disclosure, the secondary battery is at least one of lithium-ion battery, sodium ion battery, potassium ion battery, and aluminum ion battery.

According to the secondary battery provided by the embodiment of the present disclosure, the cycle performance of the secondary battery can be further optimized, and the specific capacity of the battery quality can be more stably maintained after longer circulation.

According to the fifth aspect of the present disclosure, provides use of the secondary battery in the fields of 3C, energy storage and power batteries.

According to some embodiments of the present disclosure, the 3C field comprises at least one of computer product, communication product, and consumer electronics product.

According to some embodiments of the present disclosure, the field of power batteries comprises the field of new energy vehicles.

### BRIEF DESCRIPTION OF DRAWINGS

The following is a further explanation of the present disclosure in conjunction with the accompanying drawings and embodiments, wherein:

FIG. 1 is a schematic diagram of the secondary battery negative electrode plate loaded with the passivation layer obtained in Example 1 of present disclosure;

FIG. 2 is a cycle curve for the lithium batteries consisting of untreated commercial negative electrode plates, and negative electrode plates prepared in Example 1 and Comparative Examples 1-2 of present disclosure;

FIG. 3 is a cycle curve for the lithium batteries consisting of untreated commercial negative electrode plates, and negative electrode plates prepared in Examples 3-6 of present disclosure;

FIG. 4 is a specific capacity-voltage curve of the lithium batteries consisting of untreated commercial negative electrode plates, and negative electrode plates prepared in Example 1 and Comparative Example 1 of present disclosure at first cycle and the 100^{th} cycle;

FIG. 5 is the cycle performance result for the lithium batteries consisting of untreated commercial negative electrode plates, and negative electrode plates prepared in Example 1 and Comparative Examples 1 of present disclosure;

FIG. 6 is a rate performance curve for the lithium batteries consisting of untreated commercial negative electrode plates and negative electrode plates prepared in Example 1 of present disclosure.

### REFERENCE NUMERALS

100: negative electrode plate, 110: current collector, 120: negative electrode coating layer; 200: passivation layer, 210: first passivation layer, 220: second passivation layer.

### DETAILED DESCRIPTION

The concept of the present disclosure and the resulting technical effects will be clearly and completely described below in conjunction with examples, so that the aims, features, and effects of the present disclosure can be fully understood. It is clear that the described examples are merely some rather than all of examples of the present disclosure. All other examples obtained by those skilled in the art based on examples of the present disclosure without creative labor shall fall within the protection scope of the present disclosure.

In the description of the present disclosure, the description with reference to the terms “one embodiment”, “some embodiments”, “exemplary embodiment”, “example”, “specific example”, “some examples” etc. refers to the particular features, structures, materials or characteristics described in combination with the embodiment or example are included in at least one embodiment or example of the present disclosure. In this specification, the exemplary expression of above terms does not necessarily refer to the same embodiments or examples. Furthermore, the specific features, structures, materials, or characteristics described can be combined in any suitable manner in any one or more embodiments or examples.

Unless otherwise specified, the commercial graphite negative electrode plate 100 used in the embodiments of the present disclosure comprises a current collector 110 and a negative electrode coating 120 coated thereon, which is purchased from Canrd, the plate number is SM0201, the active material ratio is 95.7%, the material gram capacity: 330 mAh/g (0.005-2.0 V), the current collector has a thickness of 8 μm, and the coating surface density is about 5.8 mg/cm² (at different positions, the surface density after compaction may fluctuate within a certain range). The commercial graphite negative electrode plate does not be rolled. Specific examples of the present disclosure are described in detail below.

### Example 1

This example prepares a CoₓO—Al₂O₃ double passivation layer (x=0.75-1), this passivation layer is deposited on a commercial graphite negative electrode plate, and the preparation method is atomic layer deposition method, which specifically comprises the following steps:
A′1. a commercial graphite negative electrode was placed into a chamber of an atomic layer deposition system, vacuumizing by using a mechanical pump to reduce the air pressure of the chamber to 0.01 Torr, then a small amount of nitrogen (100 sccm) was introduced to keep the fluidity of inert gas inside the chamber;
A′2. a first passivation layer 210 (the material was CoₓO film) was deposited on the surface of the electrode plate by using the atomic layer deposition method;
A′2a. pulsing a precursor bis(2,2,6,6,-tetramethyl-3,5-heptanedioate) cobalt was pulsed into a reaction chamber at 150° C. The valve opening and closing time was 1 s, the reaction chamber pressure reached 15 Torr, the pressure maintaining time of the precursor was 5 s, the number was 1 time. A cobalt atomic layer was formed;
A′2b. 2000 sccm nitrogen was introduced to purge, time was 30 s;
A′2c. the reactant ozone (O₃) was introduced into the reaction chamber. The pressure of the reaction chamber reached 5 Torr, time of maintaining was 15 s, the number was 5 times, and a second reactant adsorption layer was obtained;
A′2d. 2000 seem of nitrogen was introduced to purge, time was 60 s;
A′2e. steps A′2a to A′2d were cycled, the cycle number was 40 times, and a first passivation layer with a thickness of 1.6 nm was obtained;
A′3. the second passivation layer 220 (the material was Al₂O₃ film) was deposited on the surface of the first passivation layer CoₓO using the atomic layer deposition method;
A′3a. a precursor trimethylaluminum was pulsed into the reaction chamber at 150° C. The valve opening and closing time was 0.5 s, the reaction chamber pressure reached 2 Torr, the pressure maintaining time of the precursor was 1.5 s, the number was 2 times, and an aluminum atomic layer was obtained;
A′3b. 2000 sccm N₂ was introduced to purge, time was 30 s;
A′3c. O₃ was introduced into the reaction chamber. The pressure of the reaction chamber reached 2 Torr, time of maintaining: 15 s, the number was 2 times, and a second reactant adsorption layer was obtained;
A′3d. 2000 sccm N₂ was introduced to purge, time was 60 s;
A′3e. steps A′3a-A′3d were cycled, the cycle number was 5 times, and the negative electrode plate 100 loaded with the passivation layer 200 was obtained. The Al₂O₃ film had a thickness of 1.6 nm.

By controlling the number of the cycles in step A′2e and step A′3e, this example also obtained CoₓO—Al₂O₃ double passivation layers (x=0.75-1) with a thickness of 1 nm/0.1 nm, 10 nm/0.1 nm, 10 nm/5 nm and 5 nm/0.5 nm.

### Example 2

This example prepares a CoₓO—ZrO₂ double passivation layer (the value range of x is the same as in Example 1), this passivation layer is deposited on a commercial graphite negative electrode plate, and the preparation method is atomic layer deposition, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the chamber;
A′2. a CoₓO base layer film was plated on the surface of the electrode plate by atomic layer deposition method;
A′2a. a precursor bis(2,2,6,6,-tetramethyl-3,5-heptanedioate) cobalt was pulsed into the chamber of ALD at 150° C. The valve opening and closing time: 1 s, the ALD reaction chamber pressure reached 15 Torr, the pressure maintaining time of the precursor was 5 s, the number was 1 time, and a cobalt atomic layer was obtained;
A′2b. 2000 sccm N₂ was introduced into the above chamber and time of purging was 30 s;
A′2c. the ozone (O₃) was introduced into the reaction chamber. The pressure of the ALD reaction chamber reached 5 Torr, time of maintaining: 15 s, the number was 5 times, and a second reactant adsorption layer was obtained;
A′2d. 2000 sccm N₂ was introduced into the reaction chamber and time of purging was 60 s;
A′2e. steps A′2a to A′2d were cycled, the cycle number was 40 times, and a first passivation layer was obtained;
A′3. a ZrO₂ top layer film was deposited on the surface of the electrode plate by atomic layer deposition method;
A′3a. a precursor tetrakis(dimethylamino)zirconium was pulsed into the reaction chamber at 150° C. The valve opening and closing time: 0.5 s, the ALD reaction chamber pressure reached 2 Torr, the pressure maintaining time of the precursor was 1.5 s, the number was 2 times, and a zirconium atomic layer was obtained;
A′3b. 2000 sccm N₂ was introduced into the above chamber and time of purging was 30 s;
A′3c. deionized water was introduced into the reaction chamber. The pressure of the ALD reaction chamber reached 15 Torr, time of maintaining: 20 s, the number was 5 times;
A′3d. 2000 sccm N₂ was introduced and time of purging was 120 s;
A′3e. steps A′3a to A′3d were cycled, the cycle number was 5 times, and the negative electrode plate loaded with the passivation layer was obtained.

### Example 3

This example prepares a FeₓO—Al₂O₃ double passivation layer (x=0.67-1), this passivation layer is deposited on a commercial graphite negative electrode plate, and the preparation method is an atomic layer deposition method, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the chamber;
A′2. a FeₓO layer (first passivation layer) was deposited on the surface of the electrode plate by atomic layer deposition method;
A′2a. a precursor ferrocene was pulsed into the reaction chamber at 200° C. The valve opening and closing time: 1 s, the ALD reaction chamber pressure reached 15 Torr, the pressure maintaining time of the precursor was 10 s, the number was 1 time, and an iron atomic layer was obtained;
A′2b. 2000 sccm N₂ was introduced into the above chamber to purge for 60 s;
A′2c. the reactant ozone (O₃) was introduced into the reaction chamber. The pressure of the ALD reaction chamber reached 5 Torr, time of maintaining: 15 s, the number was 5 times, and a second reactant adsorption layer was obtained;
A′2d. 2000 sccm N₂ was introduced into the above chamber to purge for 120 s;
A′2e. steps A′2a-A′2d were cycled, the cycle number was 30 times, and a first passivation layer was obtained;
A′3. an Al₂O₃ layer was deposited on the surface of the negative electrode plate by using atomic layer deposition method;
A′3a. a precursor trimethylaluminum was pulsed into the reaction chamber at 150° C. The valve opening and closing time: 0.5 s, the ALD reaction chamber pressure reached 2 Torr, the pressure maintaining time of the precursor was 1.5 s, the number was 2 times, and an aluminum atomic layer was obtained;
A′3b. 2000 sccm N₂ was introduced into the above chamber to purge for 30 s;
A′3c. the reactant O₃ was introduced into the reaction chamber. The pressure of the ALD reaction chamber reached 2 Torr, time of maintaining: 15 s, the number was 2 times, and a second reactant adsorption layer was obtained;
A′3d. 2000 sccm N₂ was introduced into the above chamber to purge for 60 s;
A′3e. steps A′3a to A′3d were cycled, the cycle number was 5 times, and the negative electrode plate loaded with the passivation layer was obtained.

### Example 4

This example prepares a CuO—SiO₂ double passivation layer, this passivation layer is deposited on a commercial graphite negative electrode plate, and the preparation method is low-pressure hot-wall chemical vapor deposition, which specifically comprises the following steps:
D′1. a commercial graphite negative electrode plate was placed into a chamber of a low-pressure hot-wall chemical vapor deposition system, vacuumizing by using a mechanical pump to reduce the air pressure of the chamber to 0.01 Torr, then N₂ (2500 sccm) was introduced to clean the chamber for 15 min;
D′2. 500 sccm oxygen/ozone (O₂/O₃) mixed gas was introduced into the chamber of the hot-wall chemical vapor deposition system to reach the pressure of 1 Torr and maintain the pressure for 360 s. The ozone (O₃) oxidized the surface of the negative electrode plate and sufficient oxygen-containing functional groups were generated on the surfaces of the active substance and the binder;
D′3. 50 sccm copper acetylacetonate and 100 sccm oxygen were introduced into the reaction chamber at 200° C. The carrier gas was 2500 sccm N₂, the pressure in the reaction chamber was maintained at 0.04 Torr, the reaction time was 30 min, and a CuO film was deposited on the surface of the negative electrode plate;
D′4. 60 sccm monosilane and 1200 sccm nitrous oxide were introduced into the reaction chamber at 200° C. The plasma gas was generated by using 125W radio frequency power, the pressure in the reaction chamber was maintained at 0.3 Torr, reaction time was 5 s, and_a silicon dioxide layer was obtained. The negative electrode plate loaded with the passivation layer was obtained.

### Example 5

This example prepares a Co₂SnO₄—Al₂O₃ double passivation layer, this passivation layer is deposited on a commercial graphite negative electrode plate, and the preparation method is magnetron sputtering method, which specifically comprises the following steps:
C′ 1. a commercial graphite negative electrode plate was placed into an O₂ plasma processing system. 150 sccm O₂ was introduced and O₂ plasma was generated by using 150W of radio frequency power, to oxidize the surface of the negative electrode plate. Sufficient oxygen-containing functional groups were generated on the surfaces of the active substance and the binder;
C′2. the commercial graphite negative electrode plate was transferred into a magnetron sputtering system, and the air pressure of the chamber in system was reduced to 0.002 Torr by using a mechanical pump and a molecular pump;
C′3. 80 sccm Ar was introduced, and the pressure in the system chamber was raised to 0.01 Torr.

A pure titanium target material was sputtered by using a 150W direct current power supply. The substrate was applied at bias voltage of −50V and, rotated at 30 rad/min, time of maintaining was 3 min, and a titanium layer was deposited on the surface of the negative electrode plate;
C′4. a pure Co₂SnO₄ target material was sputtered by using a 300W radio frequency power supply. The substrate was applied at bias voltage of −50V and, rotated at 30 rad/min, maintaining time of sputtering was 30 min, and a first passivation layer with the material of Co₂SnO₄ was obtained;
C′5. a pure Al₂O₃ target material was sputtered by using a 300W radio frequency power supply, The substrate was applied at bias voltage of −50V and, rotated at 30 rad/min, maintaining time of sputtering was 5 min, and a second passivation layer with the material of Al₂O₃ was obtained. The negative electrode plate loaded with the passivation layer was obtained.

### Example 6

This example prepares a NiO—Al₂O₃ double passivation layer, this passivation layer is deposited on a commercial graphite negative electrode plate, and the preparation method is an atomic layer deposition method, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of nitrogen (100 sccm) was introduced to keep the fluidity of inert gas inside the chamber;
A′2. a first passivation layer NiO film was deposited on the surface of the electrode plate by using the atomic layer deposition method;
A′2a. a precursor bis(cyclopentadiene) nickel was pulsed into the reaction chamber at 200° C. The valve opening and closing time was 1 s, the reaction chamber pressure reached 1 Torr, the pressure maintaining time of the precursor was 5 s, the number was 1 time, and a nickel atomic layer was obtained;
A′2b. 2000 sccm nitrogen was introduced for purging, time was 30 s;
A′2c. the reactant ozone (O₃) was introduced into the reaction chamber. The pressure of the reaction chamber reached 5 Torr, time of maintaining was 15 s, the number was 3 times, and a second reactant adsorption layer was obtained;
A′2d. 2000 sccm nitrogen was introduced for purging, time was 120 s;
A′2e. steps A′2a to A′2d were cycled, the cycle number was 30 times, and a first passivation layer was obtained;
A′3. a second passivation layer Al₂O₃ film was deposited on the surface of the first passivation layer NiO by the atomic layer deposition method;
A′3a. a precursor trimethylaluminum was pulsed into the reaction chamber at 150° C. The valve opening and closing time was 0.5 s, the pressure in reaction chamber reached 1 Torr, the pressure maintaining time of the precursor was 1.5 s, the number was 2 times, and an aluminum atomic layer was obtained;
A′3b. 2000 sccm N₂ was introduced for purging, time was 30 s;
A′3c. the reactant O₃ was introduced into the reaction chamber. The pressure of the reaction chamber reached 5 Torr, time of maintaining: 15 s, the number was 2 times, and a second reactant adsorption layer was obtained;
A′3d. 2000 sccm N₂ was introduced for purging for 60 s;
A′3e. steps A′3a to A′3d were cycled, the cycle number was 5 times, and the negative electrode plate loaded with the passivation layer was obtained.

### Example 7

This example prepares a NiO—Li₃PO₄ double passivation layer, this passivation layer is deposited on a commercial graphite negative electrode plate, and the preparation method is an atomic layer deposition method, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of nitrogen (100 sccm) was introduced to keep the fluidity of inert gas inside the chamber;
A′2. a first passivation layer NiO film was deposited on the surface of the electrode plate by using the atomic layer deposition method;
A′2a. a precursor bis(cyclopentadiene) nickel was pulsed into the reaction chamber at 200° C. The valve opening and closing time was 1 s, the reaction chamber pressure reached 1 Torr, the pressure maintaining time of the precursor was 5 s, the number was 1 time. A nickel atomic layer was obtained;
A′2b. 2000 sccm nitrogen was introduced to purge, time was 30 s;
A′2c. the reactant ozone (O₃) was introduced into the reaction chamber. The pressure of the reaction chamber reached 5 Torr, time of maintaining was 15 s, the number was 3 times, and a second reactant adsorption layer was obtained;
A′2e. 2000 sccm nitrogen was introduced to purge, time was 120 s;
A′2f steps A′2a to A′2e were cycled, the cycle number was 30 times, and a first passivation layer was obtained;
A′3. a second passivation layer Li₃PO₄ film was deposited on the surface of the first passivation layer NiO by the atomic layer deposition method;
A′3a. a precursor tert-butyl lithium was pulsed into the reaction chamber at 200° C. The valve opening and closing time: 0.5 s, the reaction chamber pressure reached 0.7 Torr, the pressure maintaining time of the precursor was 20 s, the number was 1 time. A lithium atomic layer was obtained;
A′3b. 2000 sccm N₂ was introduced to purge, time was 60 s;
A′3c. the reactant H₂O was pulsed into the reaction chamber. The valve opening and closing time: 0.2 s, the ALD reaction chamber pressure reached 1 Torr, the pressure maintaining time of the H₂O was 5 s, the number was 1 time, and a second reactant adsorption layer was obtained;
A′3d. 2000 sccm N₂ was introduced to purge, time was 60 s;
A′3e. a reactant trimethylphosphate was pulsed into the reaction chamber. The valve opening and closing time: 0.5 s, the reaction chamber pressure reached 1 Torr, the pressure maintaining time of the trimethylphosphate was 5 s, the number was 1 time. A lithium atomic layer was obtained;
A′3f. 2000 sccm N₂ was introduced to purge, time was 60 s;
A′3g. steps A′3a to A′3f were cycled, the cycle number was 8 times, and the negative electrode plate loaded with the passivation layer was obtained.

### Example 8

This example prepares a CoₓO/NiO nano-laminated-Al₂O₃ double passivation layer (the value range of x is the same as in Example 1), this passivation layer is deposited on a commercial graphite negative electrode plate, and the preparation method is atomic layer deposition, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of nitrogen (100 sccm) was introduced to keep the fluidity of inert gas inside the chamber;
A′2. a first oxide film (CoₓO) was plated on the surface of the electrode plate by atomic layer deposition method;
A′2a. a precursor bis(2,2,6,6,-tetramethyl-3,5-heptanedioate) cobalt was pulsed into the reaction chamber at 200° C. The valve opening and closing time was 1 s, the reaction chamber pressure reached 1 Torr, the pressure maintaining time of the precursor was 5 s, the number was 1 time, and a cobalt atomic layer was obtained;
A′2b. 2000 sccm nitrogen was introduced to purge, time was 30 s;
A′2c. the reactant ozone (O₃) was introduced into the reaction chamber. The pressure of the reaction chamber reached 5 Torr, time of maintaining was 15 s, the number was 5 times, and a second reactant adsorption layer was obtained;
A′2d. 2000 sccm nitrogen was introduced to purge, time was 60 s;
A′2e. steps A′2a to A′2d were cycled, the cycle number was 5 times, the CoₓO layer was obtained;
A′3. a second oxide film (NiO) was plated on the surface of the electrode plate by the atomic layer deposition method;
A′3a. a precursor bis(cyclopentadiene) nickel was pulsed into the reaction chamber at 200° C. The valve opening and closing time was 1 s, the pressure of ALD reaction chamber reached 1 Torr, the pressure maintaining time of the precursor was 10 s, the number was 1 time, and a nickel atomic layer was obtained;
A′3b. 2000 sccm nitrogen was introduced to purge, time was 60 s;
A′3c. the reactant ozone (O₃) was introduced into the reaction chamber. The pressure of the reaction chamber reached 5 Torr, time of maintaining was 15 s, the number was 5 times, and a second reactant adsorption layer was obtained;
A′3d. 2000 sccm nitrogen was introduced to purge, time was 120 s;
A′3e. steps A′3a to A′3d were cycled, the cycle number was 3 times, the NiO layer was obtained;
A′4. steps A′3 to A′4 were cycled, the number was 5 times, and a first passivation layer was obtained;
A′5. a second passivation layer Al₂O₃ film was deposited on the surface of the nano-laminated layer by the atomic layer deposition method;
A′5a. a precursor trimethylaluminum was pulsed into the reaction chamber at 150° C. The valve opening and closing time was 0.5 s, the pressure of reaction chamber reached 1 Torr, the pressure maintaining time of the precursor was 1 s, the number was 1 time, an aluminum atomic layer was obtained;
A′5b. 2000 sccm nitrogen was introduced to purge, time was 15 s;
A′5c. the reactant ozone (O₃) was introduced into the reaction chamber. The pressure of the reaction chamber reached 5 Torr, time of maintaining was 15 s, the number was 2 times, a second reactant adsorption layer was obtained;
A′5d. 2000 sccm nitrogen was introduced to purge, time was 30 s;
A′5e. steps A′5a to A′5d were cycled, the cycle number was 10 times, the negative electrode plate loaded with the passivation layer was obtained.

### Example 9

This example prepares a CoₓO—Al₂O₃ double passivation layer (x=0.75-1) (the value range of x is the same as in Example 1), this passivation layer is deposited on a commercial graphite negative electrode plate, and the preparation method is roll-to-roll atomic layer deposition method for preparing a large area, which specifically comprises the following steps:
B′ 1. a negative electrode plate coil stock with a width of 1000 mm and a length of 1000 m was placed into a chamber of an atomic layer deposition system, vacuumizing the system to 0.05 Torr, and inert isolation gas with a flow rate of 400 SLM, cobalt source precursor gas used by CoₓO passivation layer material with a flow rate of 200 SLM and 500 mg/L ozone gas used by the passivation layer material with a flow rate of 200 SLM were simultaneously introduced into the chamber for atomic layer deposition;
B′2. the moving mechanism was started to enable the electrode plate to be deposited to pass through the inner cavity deposition area of five cycles in two directions for four times at the speed of 50 m/min to obtain a CoₓO layer (the first passivation layer);
B′3. when all the graphite negative electrode plates had moved forward, the cobalt source precursor carrier gas and ozone gas were turned off;
B′4. The inert isolation gas with a flow rate of 400 SLM, the trimethylaluminum precursor gas with a flow rate of 200 SLM, and the 500 mg/L ozone gas used in the passivation layer material with a flow rate of 200 SLM were simultaneously introduced into the atomic layer deposition chamber;
B′5. the moving mechanism was started to enable the electrode plate to be deposited to pass through the inner cavity deposition area of five cycles for one time at the speed of 40 m/min to obtain an Al₂O₃ layer (the second passivation layer);
B′6. when all the negative electrode plates had moved forward, the flushing gas, the trimethylaluminum carrier gas and the ozone gas were turned off. the heating was turned off, and the air was filled back;
B′7. the winding-up device was opened to move the negative electrode plate loaded with the passivation layer away.

### Example 10

This example prepares a CoₓSnO₂₊ₓ/Al₂O₃ double passivation layer (0<x<2), this passivation layer is deposited on a commercial graphite negative electrode plate, and the preparation method is atomic layer deposition method, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of nitrogen (100 sccm) was introduced to keep the fluidity of inert gas inside the chamber;
A′2. a first passivation layer 210 (the material is CoₓSnO₂₊ₓ film) was deposited on the surface of the electrode plate by using the atomic layer deposition method;
A′2a. a precursor tetrakis(diethylamine) tin was pulsed into the reaction chamber at 150° C. The valve opening and closing time was 1 s, the pressure of the reaction chamber reached 15 Torr, the pressure maintaining time of the precursor was 5 s, the number was 1 time. A tin atomic layer was formed;
A′2b. 2000 sccm nitrogen was introduced to purge, time was 30 s;
A′2c. the reactant ozone (O₃) was introduced into the reaction chamber, the pressure of the reaction chamber reached 5 Torr, and time of maintaining was 15 s;
A′2d. 2000 sccm nitrogen was introduced to purge, and time was 60 s;
A′2e. a precursor bis(2,2,6,6,-tetramethyl-3,5-heptanedioate) cobalt was pulsed into the reaction chamber at 150° C. The valve opening and closing time was 1 s, the pressure of the reaction chamber reached 15 Torr, the pressure maintaining time of the precursor was 5 s, the number was 1 time. A cobalt atomic layer was formed;
A′2f 2000 sccm nitrogen was introduced to purge, time was 30 s;
A′2g. the reactant ozone (O₃) was introduced into the reaction chamber, the pressure of the reaction chamber reached 5 Torr, time of maintaining was 15 s, the number was 5 times. A second reactant adsorption layer was obtained;
A′2h. 2000 sccm nitrogen was introduced to purge, time was 60 s;
A′2e. steps A′2a to A′2h were cycled, the cycle number was 40 times. The first passivation layer with a thickness of 1.6 nm was obtained;
A′3. a second passivation layer 220 (the material is Al₂O₃ film) was deposited on the surface of the first passivation layer CoₓSnO₂₊ₓ by using the atomic layer deposition method;
A′3a. a precursor trimethylaluminum was pulsed into the reaction chamber at 150° C. The valve opening and closing time was 0.5 s, the pressure of reaction chamber reached 2 Torr, the pressure maintaining time of the precursor was 1.5 s, the number was 2 times, and an aluminum atomic layer was obtained;
A′3b. 2000 sccm N₂ was introduced to purge, time was 30 s;
A′3c. the reactant O₃ was introduced into the reaction chamber, the pressure of the reaction chamber reached 2 Torr, time of maintaining was 15 s, the number was 2 times, and a second reactant adsorption layer was obtained;
A′3d. 2000 sccm N₂ was introduced to purge, time was 60 s;
A′3e. steps A′3a to A′3d were cycled, the cycle number was 5 times, the negative electrode plate 100 loaded with the passivation layer 200 was obtained. The obtained Al₂O₃ film had a thickness of 1.6 nm.

By controlling the cycle number of steps A′2e and A′3d, this example also obtained CoₓSnO₂₊ₓ/Al₂O₃ double passivation layers with thickness of 1 nm/0.1 nm, 10 nm/0.1 nm, 10 nm/5 nm and 5 nm/0.5 nm.

### Example 11

This example prepares a Coₓ0/MgF₂ double passivation layer (0.75<x<l), this passivation layer is deposited on a commercial graphite negative electrode plate, and the preparation method is atomic layer deposition, which specifically comprises the following steps:
A′1. a commercial graphite negative electrode plate was placed into a chamber of an atomic layer deposition system, vacuumizing by using a mechanical pump to reduce the air pressure of the chamber to 0.01 Torr, then a small amount of N₂ (100 sccm) was introduced to keep the fluidity of inert gas inside the chamber;
A′2. a CoₓO base layer film was plated on the surface of the electrode plate by atomic layer deposition method;
A′2a. a precursor bis(2,2,6,6,-tetramethyl-3,5-heptanedioate) cobalt was pulsed into the chamber of ALD at 150° C. The valve opening and closing time: 1 s, the pressure of ALD reaction chamber reached 15 Torr, the pressure maintaining time of the precursor was 5 s, the number was 1 time, a cobalt atomic layer was obtained;
A′2b. 2000 sccm N₂ was introduced into the above chamber to purge, time was 30 s;
A′2c. the ozone (O₃) was introduced into the reaction chamber, the pressure of the ALD reaction chamber reached 5 Torr, time of maintaining: 15 s, the number was 5 times, a second reactant adsorption layer was obtained;
A′2d. 2000 sccm N₂ was introduced into the reaction chamber to purge, time was 60 s;
A′2e. steps A′2a to A′2d were cycled, the cycle number was 40 times, the first passivation layer was obtained;
A′3. an MgF₂ film was deposited on the top of the surface of the electrode plate by the atomic layer deposition method;
A′3a. a precursor magnesium bis(2,2,6,6-tetramethyl-3,5-heptanedioate) was pulsed into the reaction chamber at 150° C. The valve opening and closing time: 0.5 s, the pressure of ALD reaction chamber reached 2 Torr, the pressure maintaining time of the precursor was 1.5 s, the number was 2 times, and a zirconium atomic layer was obtained;
A′3b. 2000 sccm N₂ was introduced into the above chamber to purge, time was 30 s;
A′3c. titanium tetrafluoride was introduced into the reaction chamber, the pressure of the ALD reaction chamber reached 15 Torr, time of maintaining: 20 s, the number was 5 times;
A′3d. 2000 sccm N₂ was introduced into the above chamber to purge, time was 120 s;
A′3e. steps A′3a to A′3d were cycled, the cycle number was 5 times, and the negative electrode plate loaded with the passivation layer was obtained.

### Example 12

This example prepares an electrode protection layer made of FeₓO/Al₂O₃(x=0.67-1), and this electrode protection layer is attached to a commercial graphite negative electrode plate, and the preparation method is roll-to-roll atomic layer deposition method, which comprises the specific steps of:
P1. a negative electrode plate coil stock with a width of 1000 mm and a length of 1000 m was placed into a chamber of an atomic layer deposition system, vacuumizing the system to 0.05 Torr, inert isolation gas with a flow rate of 400 SLM, mixed gas of ferrocene source precursor and nitrogen carrier gas used by a FeₓO (x=0.67-1) electrode protection layer with a flow rate of 200 SLM and 500 mg/L ozone gas used by an electrode protection layer material with a flow rate of 200 SLM were sequentially or simultaneously introduced into the atomic layer deposition chamber to obtain a FeₓO layer (the first passivation layer);
P2. the moving mechanism was started to move the deposited electrode plate to a second chamber at a speed of 10 m/min. Inert isolation gas with a flow rate of 400 SLM, mixed gas of trimethyl aluminum source precursor and nitrogen carrier gas used by the Al₂O₃ electrode protection layer with a flow rate of 200 SLM and 500 mg/L ozone gas used by the electrode protection layer material with a flow rate of 200 SLM were sequentially or simultaneously introduced into the atomic layer deposition chamber to obtain an Al₂O₃ layer (the second passivation layer);
P3. the moving mechanism was started to enable the electrode plate to be deposited to pass through the inner cavity deposition area of five cycles in two directions for four times at the speed of 10 m/min;
P4. when all the negative electrode plates had moved forward, the flushing gas, cobalt source, aluminum source precursor carrier gas and ozone gas were turned off. The heating was turned off and the air was filled back. The winding-up device was opened to remove the graphite negative electrode plate after completing the deposition processing.

### Comparative Example 1

This comparative example prepares a CoₓO single passivation layer, the passivation layer is deposited on a commercial graphite negative electrode plate, and the difference between the preparation method and that of Example 1 is:

(1) step A′4 was not included, that is, the Al₂O₃ layer did not be deposited.

### Comparative Example 2

This comparative example prepares an Al₂O₃ single passivation layer, the passivation layer is deposited on a commercial graphite negative electrode plate, and the difference between the preparation method and that of Example 1 is:

(1) step A′3 was not included, that is, the CoO layer did not be deposited.

### Test Example

The schematic structural diagram of the negative electrode plate loaded with the passivation layer obtained in example is shown in FIG. 1. It can be seen from FIG. 1 that a double ALD passivation protective layer is formed on the surface of the negative electrode plate including current collector and active material layer, wherein the active material layer comprises graphite, a binder and a conductive agent. The negative electrode plate with the double passivation protective layer can further enhance the electrochemical performance of the lithium-ion battery.

This test example also tests the performance of the negative electrode plates loaded with the passivation layer obtained in examples and comparative examples, and the specific test method comprises the following steps:

(1) Assembling of a graphite electrode plate-lithium plate half-cell. A wave elastic sheet of the button-cell shell made of 316 stainless steel (Canrd, 15.4 mmx 1.0 mm), a gasket of the button-cell shell made of 316 stainless steel (Canrd, 15.5 mm×0.5 mm), a metal lithium plate, a separator (Celgard, a thickness of 25 m, made of polypropylene) and a graphite negative electrode (Canrd SM0201) that was or was not processed by the passivation layer were sequentially placed in the button-cell shell made of 316 stainless steel (Canrd). Wherein several drops of electrolyte (graphite button battery electrolyte, Canrd KLD-1230C) were dripped into the surface of the lithium plate and the separator before and after the separator was installed. Finally, the installed battery above was compacted by using a hydraulic tablet press to complete the assembly of the half-cell buckling.

(2) Cycle test of the half-cell cycle test. The half-cell was installed on a LANHE cell test system and placed in a test environment of 25(±1) ° C. for testing. In the first 2 cycles, the battery was activated by charge and discharge at a constant current of 0.1C. In subsequent cycles, charge and discharge was performed at a constant current of 0.2C. and if it was a rate test, the charge and discharge was performed in corresponding cycle intervals at a constant current of 0.1C, 0.2C, 0.5C, 1C, 2C and 5C, each rate was subjected to 6 charge and discharge cycles, and the specific discharge capacity at the corresponding rate was the average value of the obtained results of the 6 cycles. The voltage of electrochemical performance test was 0-2.0 V.

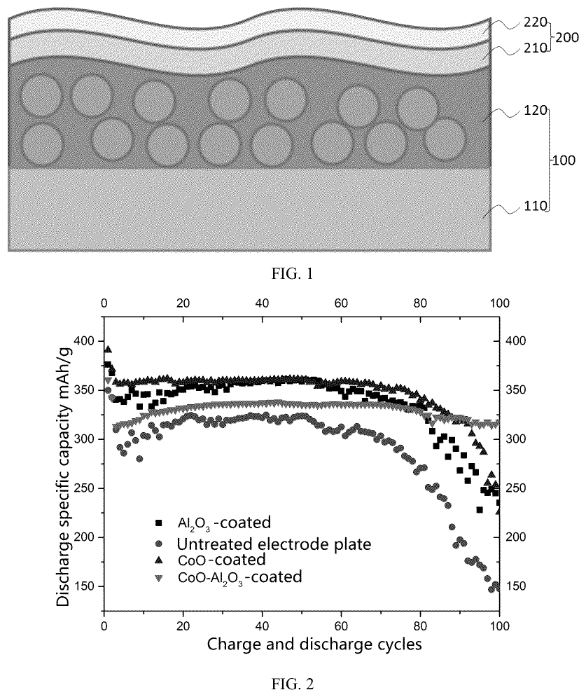

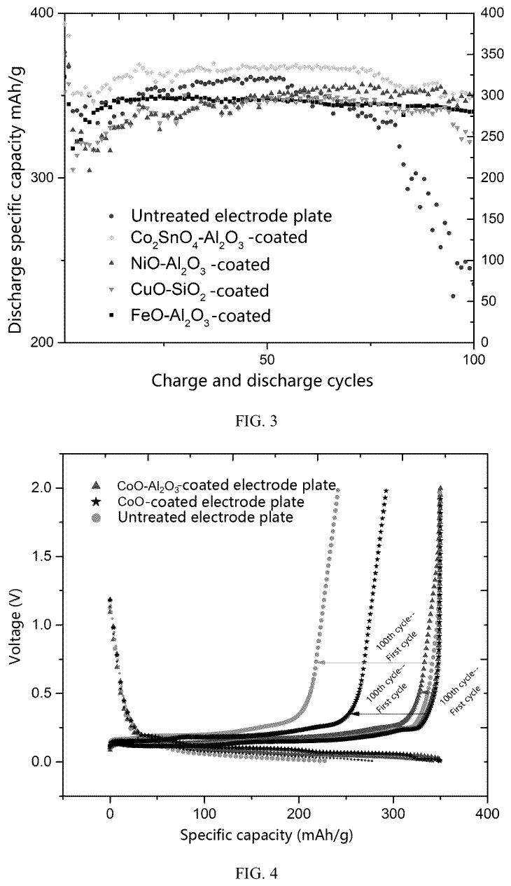

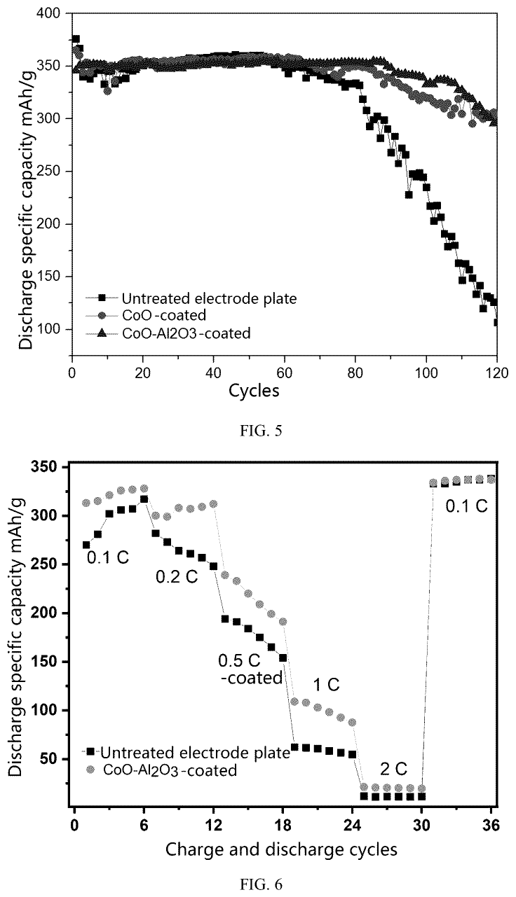

The discharge gram capacity results in the cycle process of the lithium-ion test batteries comprising the negative electrode plates obtained in Example 1 (the thickness of passivation layer is 1 nm/0.1 nm) and Comparative Examples 1 to 2 (the thickness of passivation layer is as that of the corresponding material layer of Example 1), and the negative electrode plate raw material used in Example 1 (without any treatment) are shown in FIG. 2. The cycle curves of the lithium batteries comprising untreated commercial negative electrode plate and the negative electrode plates (the thickness of passivation layer is 5 nm/0.5 nm) prepared in Examples 3-6 of the present disclosure are shown in FIG. 3. The specific capacity-voltage curves of the lithium batteries comprising the untreated commercial negative electrode plate, the negative electrode plate prepared in Example 1 (the thickness of passivation layer is 1.6 nm/1.6 nm) of the present disclosure, and the negative electrode plate prepared in Comparative Example 1 (the thickness of the passivation layer in the comparative example is the same as the that of the corresponding material of Example 1) at the first cycle and the 100^{th} cycle of are shown in FIG. 4. the cycle performance results for lithium batteries comprising untreated commercial negative electrode plate and the negative electrode plates prepared in Example 1 of the present disclosure (the thickness passivation layer is 1.6 nm/1.6 nm) and Comparative Example 1 (the thickness of the passivation layer in the comparative example is the same as the that of the corresponding material of Example 1) are shown in FIG. 5. The rate performance curves of the lithium batteries comprising untreated commercial negative electrode plate and negative electrode plate prepared in Example 1 of the present disclosure (the thickness of passivation layer is 1.6 nm/1.6 nm) are shown in FIG. 6.

It can be seen from FIG. 2 that the specific capacity of the double-layered CoₓO—Al₂O₃-coated electrode plate in Example 1 shows the slowest decreasing trend after 100 charge-discharge cycles, followed by single-layered CoₓO-coated electrode plate and single-layered Al₂O₃-coated electrode plate. In contrast, the specific capacity of the untreated commercial electrode plate begins to significantly decrease after 60 cycles, and decreases to less than 150 mAh/g after 100 charge-discharge cycles. It can draw preliminarily conclusion that coating of the single-layer atomic layer deposition film helps maintain the specific capacity of the negative electrode plate, and the use of double-layer structure can further optimize the cycle performance of lithium batteries, which can more stably maintain battery capacity after longer cycles.

The above results can be further reflected in the voltage-specific capacity diagram, that is, as shown in FIG. 4. The double-layer CoₓO—Al₂O₃-coated electrode plate has the closest specific capacity-voltage curve at the first and 100^{th} cycles, indicating that it has the best stability in charge and discharge cycles, and followed by the single-layer CoₓO-coated electrode plate. The capacity of the untreated electrode plate decreases most significantly.

FIG. 3 is the discharge gram capacity curve of the negative electrode plates obtained by multiple double passivation layer materials and multiple deposition methods in the cycle process. It can be seen that combining the double passivation layer materials provided by the present disclosure with the deposition method provided by the present disclosure can obtain a comparable effect: the specific capacity of the lithium-ion battery comprising the corresponding negative electrode has almost no decreasing trend after 100 charge-discharge cycles.

FIG. 5 is cycle performance result for CoₓO—Al₂O₃ double-layer coated electrode plate, single-layer CoₓO-coated electrode plate, and untreated electrode plate. It can be seen that the electrode plate coated by the atomic layer deposition does not influence Coulombic efficiency, and the obtained result is close to that of the untreated electrode plate.

FIG. 6 is the rate test graph of CoₓO—Al₂O₃ double-layer coated electrode plate and untreated electrode plate. It can be seen that the electrode plate coated by atomic layer deposition can also improve the rate performance of the battery to a certain extent. The specific results are shown in Table 1:

TABLE 1
Rate test results of CoₓO—Al₂O₃ double-layer
coated electrode plate and untreated electrode plate

| | | Capacity retention rate | |
|---|---|---|---|
| Current density | | Untreated electrode plate | CoₓO—Al₂O₃-coated |
| 0.1 | C | 93% | 99.9% |
| 0.2 | C | 82.9% | 94.7% |
| 0.5 | C | 57% | 77% |
| 1 | C | 18.3% | 25.2% |
| 2 | C | 3.2% | 4.8% |
| 0.1 | C | 97.9% | 99.9% |

In Table 1, the capacity retention rate is a ratio to the first-cycle discharge rate of the battery.

The cycle performance of the lithium-ion battery is also improved to varying degrees by the battery assembling the passivation layer of the negative electrode plate formed by using other substances according to the present disclosure.

The electrochemical performance of the negative electrode plate obtained in Examples and Comparative Examples is also counted in this test example, and the results are shown in Table 2.

TABLE 2
(Cycle) Performance results of Examples and Comparative Examples

| | | | First-cycle | | | |
|---|---|---|---|---|---|---|
| | | | discharging | | | |
| | | | specific | Capacity retention rate % | | |
| | | Thickness | capacity | 50 | 100 | 150 |
| | Material | (nm) | (mAh/g) | cycles | cycles | cycles |
| | — | — | 373 | 97 | 63.5 | 44.7 |
| Example 1 | CoₓO/Al₂O₃ | 1/0.1 | 369 | 98.7 | 98.6 | 97.8 |
| | CoₓO/Al₂O₃ | 10/0.1 | 370 | 99 | 98.8 | 97.5 |
| | CoₓO/Al₂O₃ | 10/5 | 366 | 98.8 | 98.7 | 97.4 |
| | CoₓO/Al₂O₃ | 5/0.5 | 368 | 98.6 | 98.5 | 97.6 |
| Example 10 | CoₓSnO₂₊ₓ/Al₂O₃ | 1/0.1 | 369 | 99 | 98.6 | 98 |
| | CoₓSnO₂₊ₓ/Al₂O₃ | 10/0.1 | 372 | 99.2 | 98.7 | 97.3 |
| | CoₓSnO₂₊ₓ/Al₂O₃ | 10/5 | 368 | 98.8 | 98.6 | 97.6 |
| | CoₓSnO₂₊ₓ/Al₂O₃ | 5/0.5 | 364 | 98.6 | 98.5 | 97.7 |
| Example 2 | CoₓO/ZrO₂ | 5/0.5 | 369 | 99.1 | 98.6 | 98.2 |
| Example 11 | CoₓO/MgF₂ | 5/0.5 | 371 | 98.6 | 98.2 | 97.6 |
| Example 3 | FeₓO/Al₂O₃ | 5/0.5 | 372 | 99.1 | 98.3 | 97.5 |
| Example 6 | NiO/Al₂O₃ | 5/0.5 | 371 | 98.3 | 98.3 | 98 |
| Example 7 | NiO/Li₃PO₄ | 5/0.5 | 367 | 98.8 | 98.6 | 97.3 |
| Example 8 | CoₓO—NiO/Al₂O₃ | 5/0.5 | 368 | 98.5 | 98.2 | 97.1 |
| Example 9 | CoₓO/Al₂O₃ | 5/0.5 | 369 | 98.7 | 98.5 | 98 |
| Example 12 | FeₓO/Al₂O₃ | 5/0.5 | 365 | 99.1 | 98.6 | 96.9 |
| Example 5 | CoₓSnO₄/Al₂O₃ | 5/0.5 | 367 | 98.6 | 95.4 | 95.2 |
| Example 4 | CuO/SiO₂ | 5/0.5 | 371 | 98.8 | 94.3 | 93.7 |

In Table 2, material refers to the material of the passivation layer, thickness refers to the thickness of the passivation layer, and “-” indicates unset or untested.

The results in Table 2 show that the passivation layer provided by the present disclosure can significantly improve the electrochemical performance of the negative electrode comprising the corresponding passivation layer. Specifically, after having the passivation layer, the capacity retention rate at 50 cycles≥98.3%, the capacity retention rate at 100 cycles≥94.3%, and the capacity retention rate in 100 cycles≥93.7%. And considering that the test example uses button battery for testing, the cycle performance can not be fully exerted. Therefore, the cycle performance of the full cell is greatly superior to the test result in Table 1 when the passivation layer provided by the present disclosure is used for the negative electrode of the full cell.

The results in Table 2 further show that, in the thickness range provided by the present disclosure, the adjustment of the thickness of each sub-layer in the passivation layer has no significant effect on the performance of the obtained negative electrode. However, the cycle performance of the obtained battery may have a certain difference based on the material composition of the passivation layer.

The above provides a detailed explanation of the examples of the present disclosure in conjunction with specific embodiments. However, the present disclosure is not limited to the aforementioned embodiments. Within the scope of knowledge possessed by ordinary skilled in the art, various changes can be made without departing from the aim of the present disclosure. In addition, the embodiments of the present disclosure and features in those embodiments can be combined with each other without conflict.

1. A passivation layer, wherein the passivation layer comprises:
a first passivation layer, wherein the first passivation layer is set on the surface of a negative electrode plate of secondary battery, having ionic conductivity and a thickness of 0.1-10 nm; and
a second passivation layer, wherein the second passivation layer is set on the surface of the first passivation layer on one side away from the negative electrode plate of the secondary battery, wherein comprising a corrosion-resistant material, with a thickness of 0.1-5 nm.

2. The passivation layer according to claim 1, wherein the first passivation layer comprises at least one of a binary oxide and a ternary oxide.

3. The passivation layer according to claim 2, wherein the binary oxide has a general formula of AOₘ;
in the AOₘ, A is selected from at least one of the group consisting of V, Mo, Nb, Sb, Ge, Sn, Cd, In, Co, 3ammy, Fe, Mn, Ni, W, Cu, Mg, Si and Cr; and 1≤m≤3.

4. The passivation layer according to claim 1, wherein the corrosion-resistant material is selected from at least one of the group consisting of Al₂O₃, HfO₂, SiO₂, ZrO₂, MgO, Si₃N₄, AlN, CaF₂, LiF, MgF₂, LiCO₃, Li₃PO₃ and LiPON.

5. A preparation method for the passivation layer according to claim 1, wherein the preparation method is: atomic layer deposition method, chemical vapor deposition method, physical vapor deposition method, or a combination thereof.

6. The preparation method according to claim 5, wherein the atomic layer deposition method comprises at least one of static atomic layer deposition method and dynamic atomic layer deposition method.

7. The preparation method according to claim 5, wherein the physical vapor deposition method is one of evaporation method, magnetron sputtering method and pulse laser deposition method.

8. A negative electrode, comprising the passivation layer according to claim 1, an active material, a binder, a conductive agent, and a current collector; preferably, the active material comprises at least one of graphite, graphene, carbon nanotubes, vapor grown carbon fibers, silicon carbon, silicon, lithium metal, sodium metal and transition metal oxides.

9. A secondary battery, comprising the negative electrode according to claim 8.

10. (canceled)

11. The passivation layer according to claim 2, the ternary oxide satisfies at least one of the general formulas shown as B₂SnO₄, CₙSnO₃, DSb₂O₆, XY₂O₄, Li₄Ti₅O₁₂, MgTi₂O₅ and TiNb₂O₇;
wherein:
in the B₂SnO₄, B is selected from at least one of the group consisting of Mg, Mn, Co and Zn;
in the CₙSnO₃, C is selected from at least one of the group consisting of Ca, Sr, Li, Mg and Co; and 1≤n≤2;
in the DSb₂O₆, D is selected from at least one of the group consisting of Co, Ni, and Cu;
in the XY₂O₄, X is selected from at least one of the group consisting of Mn, Fe, Co, Ni and Cu; Y is selected from at least one of the group consisting of Mn, Fe, Co, Ni and Cu; and the condition is that the X and the Y are different.

12. The preparation method according to claim 6, wherein the static atomic layer deposition comprises the following steps:
A1. placing the negative electrode plate of the secondary battery in a chamber of an atomic layer deposition instrument, and first sequentially depositing an adsorption layer of a first precursor and an adsorption layer of a reactant on the surface of the negative electrode plate of the secondary battery, performing cyclic deposition based on the sequence to obtain a first passivation layer; the first precursor contains non-oxygen atoms in the first passivation layer;
A2. sequentially depositing an adsorption layer of a second precursor and an adsorption layer of a reactant on the surface of the first passivation layer of the component obtained in step A1 on one side away from the negative electrode plate of the secondary battery, performing cyclic deposition based on the sequence to obtain a second passivation layer; the second precursor contains non-oxygen atoms in the corrosion-resistant material.

13. The preparation method according to claim 6, wherein the dynamic atomic layer deposition comprises the following steps:
B1. placing the negative electrode plate of the secondary battery into the chamber of atomic layer deposition instrument under the protection of isolation gas, and then purging the chamber with flushing gas;
B2. introducing the first precursor and the reactant into the deposition area of the chamber in step B1, starting the mechanical moving mechanism at the same time, enabling the negative electrode plate of the secondary battery to move through the deposition area, and depositing the first passivation layer on the surface of the negative electrode plate of the secondary battery;
B3. in the operating state of the mechanical moving mechanism, introducing the second precursor and the reactant into the deposition region in step B2, and depositing the second passivation layer on the surface of the first passivation layer on one side away from the negative electrode plate of the secondary battery.

14. The preparation method according to claim 7, wherein the magnetron sputtering method comprises the following steps:
C1. placing the negative electrode plate of the secondary battery into high vacuum magnetron sputtering system;
C2. sputtering an intermediate layer target material by using a direct-current power supply, depositing on the surface of the negative electrode plate of the secondary battery to obtain an intermediate layer;
C3. sputtering target material of the first passivation layer by using a radio frequency power supply, depositing the first passivation layer on the surface of the intermediate layer on one side away from the negative electrode plate of the secondary battery;
C4. sputtering target material of the second passivation layer by using the radio frequency power supply, depositing the second passivation layer on the surface of the first passivation layer on one side away from the negative electrode plate of the secondary battery;

15. The preparation method according to claim 5, wherein the chemical vapor deposition method is one of atmospheric pressure chemical vapor deposition method, low pressure chemical vapor deposition method and plasma enhanced chemical vapor deposition method.

16. The preparation method according to claim 15, wherein the low pressure chemical vapor deposition method comprises the following steps:
D1. placing the negative electrode plate of the secondary battery in the chamber of low pressure chemical vapor deposition system cleaned by flushing gas;
D2. simultaneously introducing the first precursor and the reactant into the chamber in step D1 to deposit the first passivation layer on the surface of the negative electrode plate of the secondary battery;
D3. simultaneously introducing the second precursor and the reactant into the chamber of step D2 to deposit the second passivation layer on the surface of the first passivation layer on one side away from the negative electrode plate of the secondary battery.

17. A negative electrode, comprising the passivation layer according to claim 4, an active material, a binder, a conductive agent, and a current collector; preferably, the active material comprises at least one of graphite, graphene, carbon nanotubes, vapor grown carbon fibers, silicon carbon, silicon, lithium metal, sodium metal and transition metal oxides.
